(19) United States
(12) Patent Application Publication
(10) Pub. No.: US 2002/0134424 A1
(43) Pub. Date: Sep. 26, 2002

(54) Photon power cell

(76) Inventor: Guy Andrew Vaz, Singapore (SG)

Correspondence Address: LADAS & PARRY, Suite 2100, 5670 Wilshire Boulevard, Los Angeles, CA, 90036-5679, US

(21) Appl. No.: 10/056,995

(22) Filed: Jan. 23, 2002

Related U.S. Application Data
(63) Continuation-in-part of application No. 09/813,457, filed on Mar. 21, 2001.

(30) Foreign Application Priority Data
Dec. 28, 2000 (SG) 200007680-2

(51) Int. Cl. H01L 25/00

(52) U.S. Cl. 136/247; 136/248

(57) ABSTRACT

A photon power cell has at least one photo-electric cell (10), one or more layers of filter glass (15) and an artificially-energised fluorescent material (20) which produces photons that are converted into electrical energy by the photo-electric cell (10). The photo-electric cell (10) may be a standard solar cell silicon wafer (14) with coatings (12) of phosphorus applied to the surfaces of the wafer (10). The fluorescent material is preferably a radioactive energised fluorescent, in which case a layer of filter glass (15) contains lead, gold and/or graphite to protect the PN junction of the solar cell (10) from unwanted radioactive particles from the radioactive-energised fluorescent material (20), while being transparent to photons within a required frequency spectrum to produce a photo-electric effect. A plurality of solar cells (10) may be arranged in a stack interposed between layers or coatings of the artificially-energised fluorescent material (20) to provide power cells which can power electrical devices such as from mobile telephones to electric vehicles for several years.

### CROSS-REFERENCE TO RELATED APPLICATIONS

This is a Continuation-in Part (CIP) of co-pending U.S. patent application 09/813,457, filed on Mar. 21, 2001.

### FIELD OF THE INVENTION

This invention relates to electrical power generation and is particularly concerned with providing a photon power cell for converting the energy of photons of light into electrical energy.

### BACKGROUND OF THE INVENTION

Various types of electrical power sources are known, ranging from small batteries to large power stations, and including solar cells which use the photo-electric effect to convert the energy of photons of light, typically sunlight, to electrical energy. There is, however, a requirement for portable electrical power generation for a multitude of applications from consumer electronics, such as CD players, radios, mobile telephones and portable computers, to higher power consumption applications, such as electric carts and cars.

### SUMMARY OF THE INVENTION

According to one aspect of the invention there is provided a photon power cell comprising:

at least one photo-electric cell, and an artificially-energised fluorescent material wherein photons from the artificially-energised fluorescent material are converted into electrical energy by the photo-electric cell.

The artificially-energised fluorescent material preferably comprises a radioactive-energised fluorescent material. It is, however, contemplated that other, non-radioactive energised artificial fluorescents which do not require sunlight, such as chemical fluorescents and bio-chemical fluorescents, could be used in the present invention.

Preferably, the photo-electric cell comprises a plurality of solar cells and the artificially-energised fluorescent material is applied to each of the solar cells.

Each solar cell wafer may conveniently comprise an industry standard silicon wafer of P-type material with diffused coatings of N-type material, such as phosphorus, applied to both major surfaces of the wafer.

However, other types of solar cells may be utilised in the present invention, for example a solar cell having a wafer of N-type material between layers of P-type material.

The photo-electric cell preferably includes one or more layers of a filter material which is substantially transparent to photons within a required frequency spectrum to produce the photo-electric effect, but which absorbs unwanted radioactive particles from the radioactive energised fluorescent material.

The layers of filter material are preferably provided between the or each solar cell wafer and the radioactive-energised fluorescent material.

In one preferred embodiment, the or each filter layer comprises glass to which radioactive particle absorbing material is added.

The radioactive energised fluorescent material may be applied to the filter layers either as a continuous coating or as a discontinuous coating, such as in substantially parallel lines or as a sputter sprayed coating.

The radioactive energised fluorescent material is preferably a chemical-radioactive fluorescent. Examples of suitable chemical-radioactive fluorescents suitable for use in the present invention include uranium-fluoride based fluorescents tritium-phosphorus fluorescents and promethium based fluorescents. It will, however, be appreciated that various other chemical-radioactive fluorescent materials may be used in the present invention, including “light fluorescents” in fluid form which are suitable for use in larger power applications.

### BRIEF DESCRIPTION OF THE DRAWINGS

A preferred embodiment of the present invention will now be described, by way of example only, with reference to the accompanying drawings, in which:

FIG. 1 is an enlarged cross-section through a photon power cell in accordance with the invention;

FIG. 2 is a schematic representation of a photon power cell comprising radioactive fluorescent material interposed between a plurality of solar cell wafers;

FIG. 3 is a front or rear view of a photon power cell showing the radioactive fluorescent material applied in parallel lines;

FIG. 4 is a front or rear view of a photon power cell showing the radioactive fluorescent material applied as a sputter spray coating; and

FIG. 5 is a schematic view of a photon power cell comprising a solar cell stack using a light fluorescent.

### DETAILED DESCRIPTION OF THE DRAWINGS

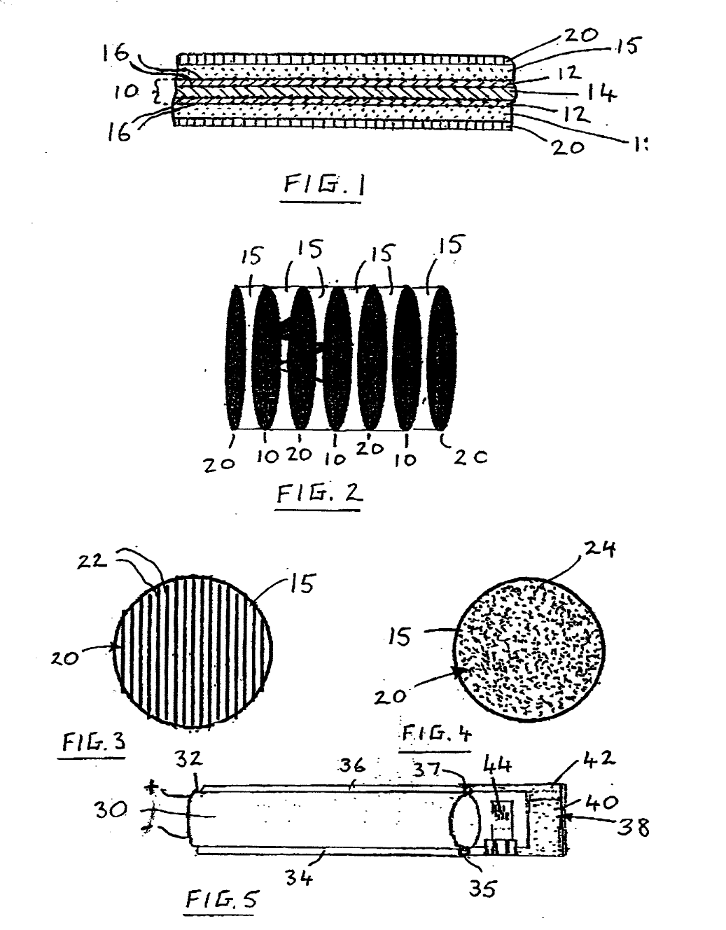

The photon power cell shown in FIG. 1 comprises a solar cell wafer 10 with filter layers 15 applied to both major surfaces of the solar cell wafer 10, and coatings 20 of chemical-radioactive material applied to the filter layers 16.

The solar cell wafer 10 may conveniently be formed from an industry standard solar cell comprising: coatings 12 of N-type material, applied to both major surfaces of a silicon wafer 14 of P-type material.

The silicon wafer 14 is typically about 200 mm in diameter. The thickness of the wafer 14 may be 300 microns (μm) or less. Preferably, the wafer has a thickness in the range of 5 to 25 microns (μm), more preferably about 15 microns (μm). The N-type material preferably comprising diffused coatings 12 of phosphorus. The boundary between each phosphorus coating 12 and the silicon wafer 14 constitutes a P-N junction across which an electric potential is developed when photons within a particular range of wavelengths impinge upon the solar cell wafer. The thickness of ‘silicon’ wafer is preferably such as to create a photo-electric effect for photons within the blue-green spectrum of light. A conducting grid 16 is applied to both sides of each phosphorus coating 12. Silver is the preferred material for the conducting grids because of its high electrical conductivity and easy diffusion to the phosphorus (N-type) material. The thickness of each conducting grid 16 is preferably about 50-75 microns (μm) high. The lines of the silver conducting grids 16 are preferably about 150-200 microns (μm) wide and are placed about 2 mm apart.

Both sides of the silicon wafer 10 are passivated with filter layers 15. The coatings 20 of chemical-radioactive fluorescent material are then applied to the outer surfaces of the filter layers 15.

The fluorescent material coating 20 has two parts: a chemical-radioactive component and a fluorescing component. The chemical-radioactive component causes the fluorescing component to glow brightly thereby providing the light source for the photon power cell. The light source in turn provides the solar wafer 10 with photons which are converted into electrical energy at the P-N junction. Generally, a brighter light source will produce more photons and therefore more power is generated by the photon power cell.

One chemical-radioactive fluorescent which has been used in a prototype power cell in accordance with the invention is tritium-phosphorus. However, other types of chemical-radioactive fluorescents can be used in the present invention, such as uranium-fluoride based fluorescents which can provide brighter light in a broad spectrum for several years. Tritium-phosphorus has a much shorter half-life of about 15 years. It is estimated that a tritium based photon power cell can effectively last for 7-10 years. Tritium-phosphorous fluorescents can be further enhanced by doping the phosphor with titanium and/or by adding thallium to the tritium-phosphorous compound. These additional elements boost the fluorescence of the phosphorous.

Another type of chemical-radioactive fluorescent which is contemplated is a promethium-based fluorescent. Promethium is a powerful source of electrons and has a Beta decay of 220 keV and a half-life of about 2.5 years. This would be suitable for small products with high power requirements.

The filter layers 15 are provided to protect the P-N junctions of the solar cell wafers 10 from unwanted radioactive particles while producing the desired frequency spectrum to obtain photon accumulation. The filter layers 15 preferably comprise glass with a radioactive-absorbing material such as gold and/or lead and/or graphite power added to the glass.

In the tritium phototype, leaded glass with about 0.05% lead is used, though it is envisaged that higher energy radioactive materials, such as radium, uranium or plutonium energised fluorescents will require higher levels of gold, lead or graphite to be added to the glass and may also require thicker glass deposition.

The fluorescent material 20 may be applied to the glass filter layers 15 in a number of different ways. FIG. 3 shows the fluorescent material 20 applied in parallel lines 22, whereas FIG. 4 shows the fluorescent material 20 applied to the glass filter layer 15 as a sputter spray 24. In a prototype, concentrated fluorescent tritium was sputter sprayed onto the glass to a thickness of about 200 microns (μm) to cover approximately 30% of the total surface of the glass filter layer 15. Whilst it is possible for the fluorescent coating 20 to cover the glass filter surface completely, this is generally not preferred for two reasons. First, the gaps allow more light to pass through and be bounced around between two wafers in a multi-layer photon power cell (see FIG. 2). Secondly, less heat is produced, thus reducing or eliminating a need for a cooling system. Tritium in gaseous form may be injected when it is required, for example before transporting the power cell.

Referring to FIG. 2, there is shown schematically a photon power cell comprising a stack of solar cell wafers 10 disposed between a plurality of layers of chemical-radioactive fluorescent material 20. Each solar cell wafer 10 is preferably of the same construction as described with reference to FIG. 1, having a silicon wafer of P-type material sandwiched between coatings of N-type material with conducting grids on each side of the P-N junctions. Glass filter layers 15 are provided between the layers of chemical-radioactive fluorescent material 20 and the solar cell wafers 10, and it will be appreciated that in the stack of FIG. 2 the chemical-radioactive fluorescent material 20 may be applied as coatings to the interposed glass filter layers 15 as described with reference to FIG. 1 and FIG. 3 or FIG. 4. Likewise, the same or similar materials may be used for the solar cell wafers 10, the filter layers 15 and the chemical-radioactive fluorescent layers 20 as described with reference to FIG. 1.

In a prototype power cell, a stack of eleven silicon solar cell wafers were packaged into a cell housing made of 0.2 mm stainless steel, with a cover separated from the base with silicone rubber.

As illustrated schematically in FIG. 2, photons emanating from the fluorescent material 20 between solar cell wafers 10 may bounce back and forth between the wafers 10 on each side. This enhances the capture and conversion of photons into electrical energy.

In the photon power cell of FIG. 2, electric terminals connected to the conducting grids of each solar cell wafer 10 of the stack can be arranged in series to produce more power than the single solar cell wafer 10 of FIG. 1.

It is envisaged that a photon power cell containing a stack of eleven solar cell wafers 10 having 22 sides treated as described above with filter layers 15 and chemical-radioactive fluorescent materials 20 could produce about 220 watts of electrical power. 120 cells coupled in series could produce about 26 kilowatts. However, this many cells coupled together is likely to require a cooling system, possibly in the form of an inner and outer jacket to contain a liquid or air coolant.

It will be appreciated that a photon power cell in accordance with the present invention has many different applications as exemplified by the following list of applications when continuous or sputter-sprayed coatings or light fluorescent coatings are used:

| | | |
|---|---|---|
| A | Very small cells for mobile | 3-5 wafers, continuous coating. |
| | hand phones | |
| B | Note book computers | 10 wafers, sputter sprayed |
| | | coating. |
| C | Very light electric car (air | 1,500 wafers, sputter spray |
| | cooled) | coating. |
| D | Electric car (water cooled) | 1,500 wafers, continuous coating |
| E | Heavy electric vehicle (water | 3,000 wafers, continuous or light |
| | cooled) | fluorescent. |
| F | Power substation | 10,000 + wafers, light |
| | | fluorescent. |

For very large kilowatt or megawatt power application, such as for homes or power stations, it is envisaged that “light fluorescents” would be used.

Light fluorescents can be provided in liquid or gaseous form and pumped into the power cell when electrical energy is needed and pumped out of the cell when energy is not required. The light fluorescents could be contained separately in a modular system.

An example of a photon power cell which uses a light fluorescent is illustrated schematically in FIG. 5. The photon power cell of FIG. 5 comprises a stack 30 of solar cell wafers contained in a casing 32 having positive (+) and negative (−) terminals. A channel 34 for a liquid light fluorescent is provided at the bottom of the stack 30 and a channel 36 for an inert gas, such as helium, is provided at the top of the stack 30. The bottom and top channels 34, 36 are connected by valves 35, 37 to a reservoir 38 for the liquid light fluorescent 40 and for inert gas 42. A two-way metering pump 44 is provided for pumping light fluorescent 40 to and from the bottom channel 34. When the power cell is not being used as a source of electrical power, light fluorescent 40 is pumped from the bottom channel 34 to the reservoir 38. When the power cell is required for use, the liquid light fluorescent 40 is pumped from the reservoir 38 to the bottom channel 34. The solar wafer stack 30 may have further channels for light fluorescent between the solar cell wafers and into which the light fluorescent is pumped when the cell is required for use.

The light fluorescent photon power cell of FIG. 5 may take a few minutes from the start of pumping to produce peak power. During this time, an industry standard battery or capacitor may be used in conjunction with the photon power cell as standby power. In order to satisfy larger power requirements, it will be appreciated that a plurality of photon power cells of the type shown in FIG. 5 may be provided in series.

In a photon power call which is gas filled, an inert gas, such as Xenon or Krypton, may be added in the gas to improve the luminescence. Further, the addition of such inert gases broadens the spectrum of the light photons. For example, a phosphorous fluorescent by itself may provide a spectrum from 400-600 nanometers (nm), whereas the addition of an inert gas may broaden the spectrum to approximately 300-900 nanometers. This “white light” spectrum provides more latitude in designing the photoelectric cells.

In order to convert the relatively low level of light having a band width of 400-600 nm produced by a trituim-phosphorous fluorescent efficiently into electrical energy required a very thin photovoltaic cell, e.g. of only about 10-20 microns thick, and a conducting grid etched deep into the thin silicon wafer of the cell to adhere a band-gap of about 5 microns. Thus it was theoretically possible to pile photovoltaic cells of a thickness 10-20 microns one on top of another such that 50 photovoltaic cells could be 1 mm high. However, a very thin layer of silicon is very delicate, and so such a photovoltaic cell is very difficult to make because a layer of fluorescent material has to be applied to the face of each photovoltaic cell. Furthermore, in a gas filled cell, a sufficient space must be provided for the radioactive gas to flow between and saturate the fluorescent material.

With the use of a white-light fluorescent including promethium and an inert gas, such as Xenon or Krypton, thicker, cheaper and stronger photovoltaic cells can be used to reduce cost and damage. This allows a much wider range of photovoltaic cells to be used.

Photon power cells in accordance with the invention can provide continuous electrical power for several years in small portable packages. For example, a photon power cartridge measuring 25 mm by 50 mm by 10 mm thick could power a mobile hand phone for about seven years, while a 100 mm by 100 mm by 1.2 thick cartridge could power a notebook computer for about seven years. A larger photon power package measuring 1.2 m long×200 mm by 200 mm could supply an electric vehicle with about 32 kw for about 10 years continuously.

Further details of the construction of these three types of power cells will now be described.

Photon cell for hand phones

A photon cell construction for a hand phone may be as follows.

The fluorescent is deposited on a 25-micron silicon wafer and electrical grid lines are etched deep into the silicon wafer. The wafer is cut in smaller pieces 3 cm by 3 cm.

The fluorescent compound with the radioactive isotope incorporated into the mixture is deposited onto the 3 cm by 3 cm cell. A reinforcing back plane is attached for strength and to improve connectivity to the other photovoltaic cells.

The “Photon cell” comprising the reinforcing and connecting back plane, the photovoltaic cell, the radioactive isotope and fluorescent compound, is about 60-70 microns thick. 22 photon cells are layered one on top of another and connected in series to achieve a 3 volts power supply. The 3-volt pack is about 1.8 millimeter thick (including the resin packing). 3 of these packs may be placed one on top of each other and connected in parallel to provide the desired wattage.

The entire photon pack is about 6 millimeter thick and measures 3.1 cm by 3.2 cm. It may be encased in an airtight stainless case made of 0.2 millimeter stainless steel, with only the electrical leads protruding.

The finished product comprises a photon pack, a power regulator chip (which may be a standard item), and a rechargeable Lithium Ion battery.

It is set up such that the hand phone drains the battery and the photon pack recharges the battery slowly.

Photon cell for Notebook computer and or Military transceivers

The basic difference in this application is:

(a) Promethium may be used in packs for Military transceivers and Military Battlefield computers whilst Tritium may be used for civilian applications. The civilian applications have less than half the power of the military applications.

(b) The photovoltaic cells are much larger, either 5 cm by 5 cm or 9 cm by 9 cm.

(c) The photovoltaic cells are much thicker, each layer is 90-100 micron thick and each layer is packed in a less dense configuration.

(b) The radioactive isotope and fluorescent mixture is waxy and more fluid than the mixture in hand phones which is a very viscous paste and hardens in time to form a strong bonded layer. The more fluid mixture in this application provides much greater resistance to knocks, shocks, and rough use.

(c) Since these units have positive pressure, more Promethium/Thallium/Tritium is injected into the stainless steel case after final assembly. These units can be recharged with fresh radioisotope gas when power levels drop.

On the outward appearance, the casing is further reinforced.

In its completed form, the same power-regulating chip (e.g. purchased from Infinion) is used and a Lithium Ion or Metal Hydride rechargeable battery is used. The military units have the option of using “Carbon-Carbon Ultra Capacitors” instead of rechargeable batteries.

Photon cell for an electric car or other vehicle

The design for the electric car is a mobile self-contained unit that can be used as an auxiliary generator for any home, boat, etc.

The basic differences are:

(a) The photovoltaic cells are very large, measuring about 200 millimeters (8 inches) in diameter.

(b) The photovoltaic cells are also thicker i.e. approximately 100 microns.

(c) The fluorescent material is the same as in the military transceivers but the coating is very much thicker at about 200-300 microns.

(d) the next significant difference is the flow grid. Since the cells are so large, a grid of channels is formed into layers of fluorescent material to allow the radioactive isotope gas to flow more freely.

(e) This design is also under positive pressure however, the system comes with a pump and an addition canister of radioisotope gas. When more power is needed, the pump will pump more radioisotope gas into the photon cells and draw it out when the power requirements are low.

(f) The added advantage is that the system can very easily be re-used by simply changing the radioisotope gas cylinder with a fresh gas cylinder.

It will be appreciated that various modifications may be made to the embodiments of the present invention as described above without departing from the scope and spirit of the present invention as defined in the claims. For example, it may be possible to use gallium arsenide solar cells instead of silicon based solar cells. Also, radioactive waste material may be used since harmful particles are depleted.

1. A photon power cell comprising at least one photo-electric cell and an artificially-energised fluorescent material, wherein photons from the artificially-energised fluorescent material are converted into electrical energy by the photo-electric cell.

2. A photon power cell according to claim 1 wherein the photon power cell comprises a plurality of solar cells with the artificially-energised fluorescent material applied to each of the solar cells.

3. A photon power cell according to claim 2 wherein each solar cell comprises a wafer of P-type or N-type material, and layers or coatings of N-type or P-type material respectively applied to surfaces of the wafer.

4. A photon power cell according to claim 2 wherein the solar cell comprises a wafer of silicon P-type material with diffused coatings of phosphorus applied to both sides of the wafer.

5. A photon power cell according to claim 2 wherein the plurality of solar cells are arranged in a stack.

6. A photon power cell according to claim 1 wherein the artificially-energised fluorescent material is a radioactive-energised fluorescent material.

7. A photon power cell according to claim 6 wherein the or each photo-electric or solar cell includes at least one layer of filter material which is substantially transparent to photons within a required frequency spectrum to produce a photo-electric effect, but which absorbs radioactive particles from the radioactive-energised fluorescent material.

8. A photon power cell according to claim 7 wherein the at least one layer of filter material is provided between the or each photo-electric or solar cell and the radioactive-energised fluorescent material.

9. A photon power cell according to claim 7 wherein the at least one layer of filter material comprises glass to which a radioactive particle-absorbing material is added.

10. A photon power cell according to claim 9 wherein the radioactive particle-absorbing material comprises any one or more of the following: lead, gold and/or graphite powder.

11. A photon power cell according to claim 7 wherein the radioactive-energised fluorescent material is applied as a coating to the at least one layer of filter material.

12. A photon power cell according to claim 11 wherein the radioactive-energised fluorescent material is a continuous coating applied to the at least one layer of filter material.

13. A photon power cell according to claim 12 wherein the radioactive-energised fluorescent material is a discontinuous coating.

14. A photon power cell according to claim 13 wherein the radioactive-energised fluorescent material is applied to the at least one layer of filter material in substantially parallel lines.

15. A photon power cell according to claim 14 wherein the radioactive-energised fluorescent material is applied as a sputter coating to the at least one layer of the filter material.

16. A photon power cell according to claim 13 wherein the radioactive-energised fluorescent material covers approximately 30% of the at least one layer of filter material.

17. A photon power cell according to claim 6 wherein the radioactive fluorescent material comprises a chemical-radioactive fluorescent.

18. A photon power cell according to claim 17 wherein the chemical-radioactive fluorescent material is tritium-phosphorus based.

19. A photon power cell according to claim 17 wherein the chemical-radioactive fluorescent material is uranium-fluoride based.

20. A photon power cell according to claim 1 wherein the artificially-energised fluorescent material comprises a non-radioactive, chemical fluorescent.

21. A photon power cell according to claim 1 wherein the artificially-energised fluorescent material comprises a bio-chemical fluorescent.

22. A photon power cell according to claim 1 wherein the artificially -energised fluorescent material comprises a light fluorescent in fluid form.

23. A photon power cell according to claim 19 wherein the light fluorescent fluid is pumped into the power cell when power is required and pumped out of the power cell when the cell is not in use.
